(19) United States
(12) Patent Application Publication
(10) Pub. No.: US 2014/0159744 A1
(43) Pub. Date: Jun. 12, 2014

(54) ELECTRICAL DEVICE

(71) Applicant: ABB Technology AG, Zurich (CH)

(72) Inventors: Adrian HOZOI, Mannheim (DE); Rolf Disselnkötter, Mauer (DE)

(73) Assignee: ABB Technology AG, Zurich (CH)

(21) Appl. No.: 14/157,195

(22) Filed: Jan. 16, 2014

Related U.S. Application Data
(63) Continuation of application No. PCT/EP2012/001362, filed on Mar. 28, 2012.

(30) Foreign Application Priority Data
Jul. 16, 2011 (EP) PCT/EP2011/003554

(51) Int. Cl. G01R 19/00

(52) U.S. Cl. CPC G01R 19/0092
USPC 324/654

(57) ABSTRACT

An exemplary electrical device for measuring alternating current or current pulses includes at least one coil of electrically conductive wire being wound around a non-magnetic carrier, where the non-magnetic carrier is made of glass.

### RELATED APPLICATION(S)

This application claims priority under 35 U.S.C. §120 to International application PCT/EP2012/001362 filed on Mar. 28, 2012, designating the U.S., and claim priority to International application PCT/EP2011/003554 filed on Jul. 16, 2011. The entire content of each prior application is hereby incorporated by reference in its entirety.

### FIELD

The disclosure relates to an electrical device and more particularly to an electrical device for measuring alternating current or current pulses which consists of a coil of wire wound around a non-magnetic carrier.

### BACKGROUND INFORMATION

Known Rogowski coils can be constructed by applying an electrically conductive wire on a non-magnetic and non-conductive carrier, which can be a plastic based structure and forms a closed or almost closed loop, such that a kind of toroidal coil of wire is formed, wherein the wire is arranged in a helix on a toroidal carrier so that a toroidal coil is formed. The lead from one end of the coil may return through the centre of the coil or close to the centre of the coil to the other end, so that both terminals are at the same end of the coil and so that the toroidal coil itself does not form a closed loop, like in FIG. 7. The return wire may not be specified in some applications.

The Rogowski coil belongs to the category of air-core coils since the carrier of the coil is non-magnetic, e.g., its magnetic susceptibility is significantly smaller than one. The carrier may be rigid or flexible and its shape may be toroidal or like an oval ring, but other shapes are also possible. Additionally, the Rogowski coil may consist of one single coil, as shown in FIG. 7, or an arrangement of multiple coils, as exemplary shown in FIG. 8, in which case the shape of the coils may be straight or curved.

When placed around a primary conductor carrying an electrical current, the Rogowski coil can generate a voltage proportional to the derivative of the current according to Ampere's law. The voltage is also proportional to the number of turns per unit length and to the area of the turns. The area of one turn is equal to the area enclosed by one single complete turn and is approximately equal to the cross section area of the coil carrier.

Since the voltage induced in the Rogowski coil is proportional to the rate of change of current in the primary conductor, the output of the coil can be connected to an electronic device where the signal is integrated and eventually further processed in order to provide an accurate signal that is proportional to the current flowing through the primary conductor.

The Rogowski coil has many advantages compared to other types of current measuring devices, the most notable being the excellent linearity due to its non-magnetic core which is not prone to saturation effects. Thus, the Rogowski coil is highly linear even when subjected to large currents, such as those used in electric power transmission, welding, or pulsed power applications. Furthermore, since a Rogowski coil has a non-magnetic core, it features very low inductance and can respond both to slow- and fast-changing currents resulting in a wide frequency range of operation. A correctly formed Rogowski coil has winding turns which are uniformly spaced and which have equal or almost equal area in order to be largely immune to electromagnetic interference. A non-magnetic material designates here any material whose magnetic susceptibility has a magnitude or value lower than one.

Despite numerous advantages in the use of Rogowski coils mentioned before, the accuracy and the reliability of the Rogowski coil strongly depends on the accuracy and uniformity of the coil winding and of the area of the turns.

The quality of the winding again depends on the winding process and on the coil carrier employed while the area of the turns depends mainly on the coil carrier. The carriers of Rogowski coils can be manufactured using various types of plastic based materials, thermosetting or thermoplastic. The plastic materials may contain fillers such as glass fiber or silica particles in order to improve their mechanical and dimensional properties.

However, for these plastic based materials it can be very difficult to decrease the coefficient of thermal expansion below 25 ppm/K and additionally the coil carriers can be subject to deformations caused by mold shrinkage and water absorption. The initial tolerances of plastic based coil carriers cannot be kept within tight limits and can hardly come close to +/−0.05 mm. The moderate tolerances negatively impact the winding process and may affect both the accuracy and the uniformity of the winding turns.

The drifts and deformations of plastic materials are often non-uniform due to anisotropic properties which can be induced by the orientation of the polymer molecules and/or glass fiber fillers during the molding process. Non-uniform deformations and non-uniform winding turns decrease the immunity of the Rogowski coil against electromagnetic interference and pick-up of parasitic signals, and result in degraded accuracy and reduced reliability.

The initial error caused by the tolerances of the carrier and the drift caused by the thermal expansion of the carrier can be too high for high accuracy applications and should be corrected, for example by means of the electronics conditioning the signal of the Rogowski coil, whereas only the errors caused by uniform deformations can be partly corrected. The errors caused by non-uniform deformations and non-uniform winding cannot be reduced. Even in complex systems with sophisticated correction means it can be very difficult to ensure good accuracy over wide temperature ranges.

Hence exemplary embodiments of the present disclosure provide an electrical device with a carrier, for example a Rogowski coil, that addresses the above-noted challenges overcome while also making production is easy and favourable.

### SUMMARY

An exemplary electrical device for measuring alternating current or current pulses is disclosed, comprising: at least one coil of electrically conductive wire being wound around a non-magnetic carrier, wherein the non-magnetic carrier is made of glass.

### BRIEF DESCRIPTION OF THE DRAWINGS

Through the accompanied drawings, exemplary embodiments, features and specific advantages of the disclosure shall be explained and illustrated in more detail.

It is shown in

FIG. 1 illustrates a glass coil carrier with a toroidal shape having an oval cross section according to an exemplary embodiment of the disclosure;

FIG. 2 illustrates a glass coil carrier with a toroidal shape having a circular cross section according to an exemplary embodiment of the disclosure;

FIG. 3 illustrates a glass coil carrier in the shape of an elliptic ring where the cross section of the coil may be of any suitable shape according to an exemplary embodiment of the disclosure;

FIG. 4 illustrates a glass coil carrier in the shape of a rectangular ring where the cross section of the coil may be of any suitable shape according to an exemplary embodiment of the disclosure;

FIG. 5 illustrates a glass coil carrier with a toroidal shape having a groove for the return wire applied in the midplane of the carrier according to an exemplary embodiment of the disclosure;

FIG. 6 illustrates a glass coil carrier with a toroidal shape having a groove for the return wire according to an exemplary embodiment of the disclosure;

FIG. 7 illustrates an electrical device having a glass carrier, a toroidal coil and a return wire, used as a Rogowski coil according to an exemplary embodiment of the disclosure;

FIG. 8 illustrates an electrical device having an assembly of four coils with straight glass carriers, wherein the coils are uniformly and symmetrically arranged and wherein the assembly is used as a Rogowski coil according to an exemplary embodiment of the disclosure.

### DETAILED DESCRIPTION

Exemplary embodiments of the present disclosure are directed to an electrical device that includes at least one coil of electrically conductive wire being wound around a non-magnetic carrier, wherein the non-magnetic carrier is made of glass.

According to one exemplary embodiment of the disclosure, the carrier of electrical device, for example a Rogowski coil, is made of glass by means of a process such as glass molding or pressing. Furthermore, the glass material may include mainly silicon dioxide mixed with other components such as Na₂O, CaO, Al₂O₃, B₂O₃, etc.

Depending on the processing method employed, the glass material can be formed after being heated at a temperature which exceeds at least the glass transition temperature (Tg). Glass materials with lower Tg can thus be processed at lower temperatures.

Glass does not suffer from mold shrinkage and very good tolerances and surface quality can be obtained. Furthermore, due to the high content of silicon dioxide, glass is featuring excellent physical and chemical stability over very wide temperature range. Its properties can feature very low thermal drift, excellent aging withstand, no water absorption, and good solvent resistance. The material can be isotropic due to its amorphous structure, resulting in excellent uniformity of its physical properties. Many types of glasses are commercially available with different physical properties such as different glass transition temperatures and coefficients of thermal expansion.

Best known, most widespread, and lowest cost is the soda-lime glass, which features glass transition temperature of about 570° C. and a coefficient of thermal expansion of approximately 9 ppm/K. Significantly lower thermal expansion coefficient can be achieved with other glass types, which may advantageously be used, such as borosilicate glass which is readily available with thermal expansion coefficient around 3 ppm/k and glass transition temperature around 525° C.

According to another exemplary embodiment, in order to enhance an easy and beneficial production of the coil carriers, such as glass materials with low glass transition temperature, for example between 200° C. and 700° C., are used since their processing parameters result in an increase of lifetime of molds and reduction of process time. The coefficient of thermal expansion of such glass materials can be between 2 ppm/K and 15 ppm/K, depending on the composition of the material.

The coil carriers can be made of glass exhibit much lower tolerances, better uniformity, wider temperature range, and better stability than hitherto existing and produced plastic based counterparts. Excellent mechanical and chemical stability can be ensured including low thermal drift, no long term deformations, no water absorption, and solvent resistance. Moreover, glass materials are widely available and easy to process at competitive cost compared to the plastic based counterparts.

The low tolerances and the uniform structure of the glass carrier make it possible to achieve uniform winding of the coil that contributes to achieving high accuracy and high immunity against electromagnetic interference.

Exemplary electrical devices according to the present disclosure, as for example Rogowski coils, constructed on glass carriers feature many benefits with respect to prior art coils based on plastic materials. Benefits provided by the embodiments disclosed herein include excellent accuracy, excellent long-term stability, excellent immunity against electromagnetic interference, wide operation temperature range, no compensation of thermal drifts, and about the same production efforts as compared to plastic based carriers.

According to an exemplary embodiment the glass carrier of the electrical device, for example the Rogowski coil, can be formed by traditional molding or pressing techniques with tight tolerances down to +/−0.02 mm and with good surface finish, that is better than can be achieved with plastic based materials.

Even better tolerances and surface finish can be achieved by employing precision glass molding, a process that was recently developed for fabricating high accuracy but low cost optical components.

Excellent tolerances in the order of +/−0.005 mm and surface roughness in the order of 5 nm can be achieved using precision glass molding, much better than with any plastic based material.

Glasses with low glass transition temperature have been developed for precision molding, featuring compositions to decrease the tendency for devitrification and to reduce the reaction with mold materials within the molding temperature range. A wide choice of those glasses exists from various manufacturers and many are also suitable for fabricating coil carriers for electrical devices and, for example, for Rogowski coils.

Examples of known precision molding glasses to be used for manufacturing coil carriers can include the P-SK57Q1 type from SCHOTT AG having a transition temperature of 439° C. and a coefficient of thermal expansion of 8.9 ppm/K, or the L-PHL1 type from Ohara Corporation having a transition temperature of 347° C. and a coefficient of thermal expansion of 10.5 ppm/K.

According to yet another exemplary embodiment, the glass carrier of the electrical device and for example of the Rogowski coil can include a closed path shape like a toroid or a ring. Various shapes of the path are possible such as circular, oval, elliptic, rectangular, or rectangular with rounded ends and/or rounded edges.

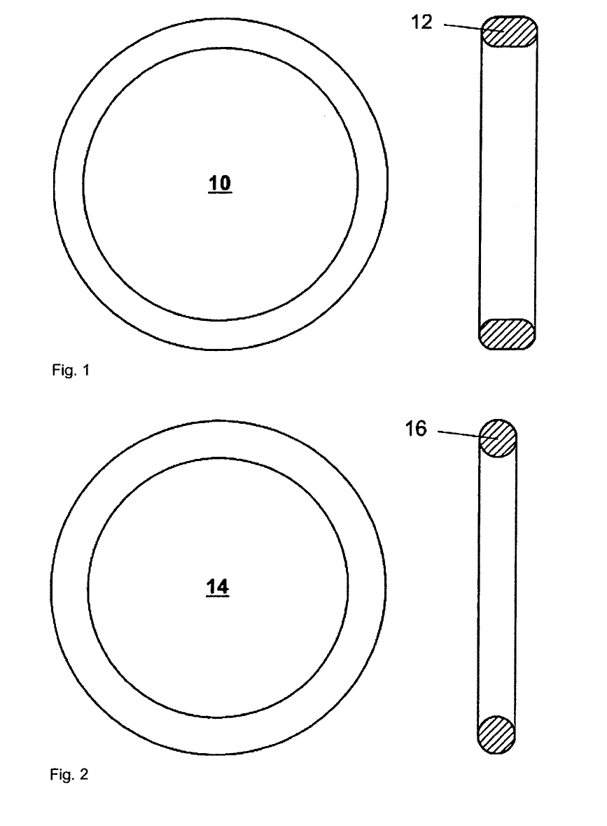

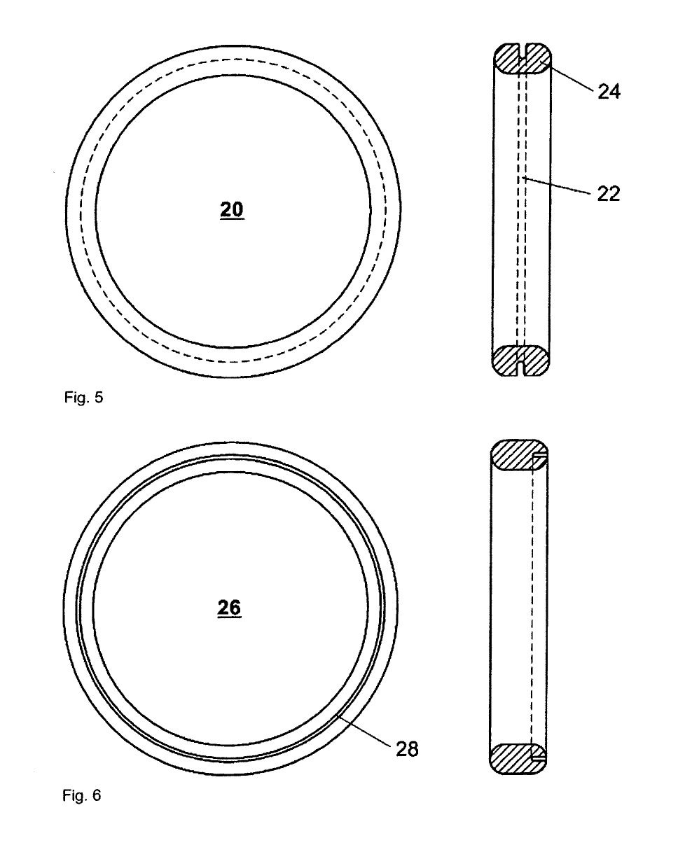

The cross section of the carrier can be oval like (shown in FIG. 1), circular like (shown in FIG. 2), or any other suitable shape such as elliptic or rectangular with rounded ends and/or rounded corners. The glass carrier may feature a groove for the return wire which is aimed to make the electrical device and/or the Rogowski coil insensitive to magnetic fields perpendicular to the path of the carrier. The cross-sensitivity would be null or zero if the depth of the groove is such that the return wire passes through the centre of the coil. However, the depth of the groove may be smaller in order to facilitate the fabrication process of the carrier and/or the winding of the core. An example of toroidal carrier provided with a groove for the return wire (shown in FIG. 5), where the groove is applied to the carrier such that two symmetric lobes are obtained. However, other implementations of the groove are possible and the groove may be applied from different directions, may have different profiles, or may have various depths. Such an example is shown in FIG. 6.

In another exemplary embodiment of the present disclosure, the path of the glass carrier may also be open, for example have one or more gaps, and/or the Rogowski coil and/or electrical device can include multiple coils at which the number of coils and their arrangement may vary.

Furthermore the electrical device, for example a Rogowski coil, can feature either a single layer winding or multiple layers for increased sensitivity. The multiple layers can feature alternating winding directions in order to make the electrical device insensitive to magnetic fields perpendicular to the path of the carrier.

Besides that the glass carrier can be covered with a thin polymer layer in order to control the friction between the coil wire and the carrier and/or to improve the adhesion of the wire to the carrier.

The electric device, for example a Rogowski coil, described in this disclosure can be partly or totally enclosed in an electrical shield in order to protect it from electrical interferences. The electrical shield can be made from one or more pieces of conductive or semi-conductive material, which can be solid or flexible, where examples of materials employed are based on metals, plastics loaded with conductive fillers, or plastics covered with one or more metallization layers.

The electric device and/or Rogowski coil can be used for a wide range of currents and various applications like electrical power transmission and distribution, electrical energy metering, AC motor control, or instrumentation. While the present disclosure originates from the area of current sensors employed in electrical power transmission and distribution, its area of application is much broader.

Moreover, a current sensor including an electrical device according to the disclosure to be employed in electrical power transmission and distribution, for example in electrical power transmission and distribution stations or switchgears, or in electrical energy metering, is disclosed and claimed and is therefore explicitly included into the claim of the present application and is consequently within the scope and the content of disclosure.

FIG. 1 illustrates a glass coil carrier with a toroidal shape having an oval cross section according to an exemplary embodiment of the disclosure. The oval or elliptic cross section 12 is advantageous in some cases because it allows reaching an elongated shape while ensuring good contact between the coil wire and the glass carrier.

FIG. 2 illustrates a glass coil carrier with a toroidal shape having a circular cross section according to an exemplary embodiment of the disclosure

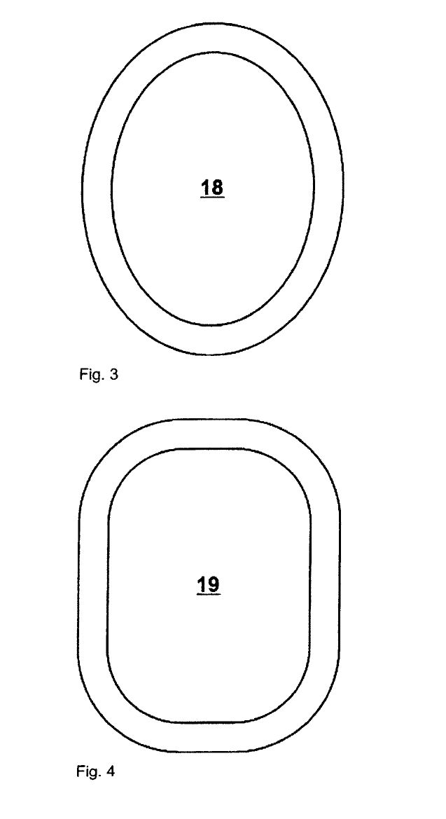

FIG. 3 illustrates a glass coil carrier in the shape of an elliptic ring where the cross section of the coil may be of any suitable shape according to an exemplary embodiment of the disclosure. The elliptic or oval ring shape of the carrier 18 may be advantageous for selected measuring applications. The cross section of the carrier 18 is not made visible in this picture and may be of any suitable shape, for example circular or oval.

FIG. 4 illustrates a glass coil carrier in the shape of a rectangular ring where the cross section of the coil may be of any suitable shape according to an exemplary embodiment of the disclosure.

FIG. 5 illustrates a glass coil carrier with a toroidal shape having a groove for the return wire applied in the midplane of the carrier according to an exemplary embodiment of the disclosure. As shown in FIG. 5, the groove is applied through the midplane of the carrier such that two symmetric lobes are obtained in the cross-sectional area. The cross section 24 of the glass carrier has the form like an oval with a hollow resulting from the groove 22, the deepest part of the hollow being approximately in centre of the oval.

FIG. 6 illustrates a glass coil carrier with a toroidal shape having a groove for the return wire according to an exemplary embodiment of the disclosure. As shown in FIG. 6, a glass carrier 26 has a groove 28 applied perpendicular to the midplane of the carrier. The depth of the groove 28 may take any value between almost zero and up to approximately the midplane of the carrier.

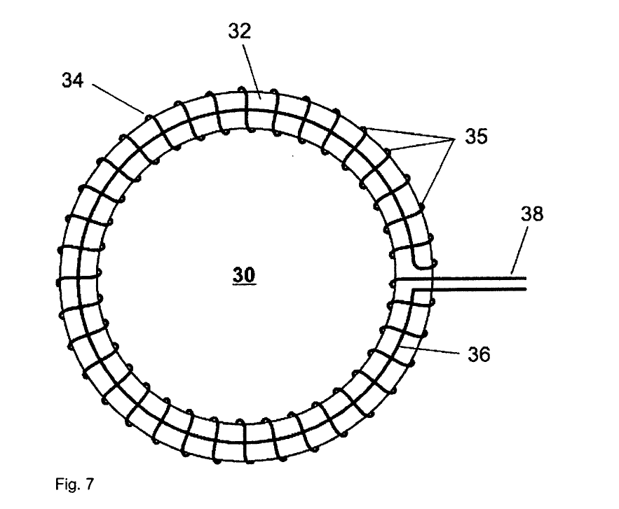

FIG. 7 illustrates an electrical device having a glass carrier, a toroidal coil and a return wire, used as a Rogowski coil according to an exemplary embodiment of the disclosure. As shown in FIG. 7, the electrical device 30 has a toroidal glass carrier 32 provided with a toroidal coil 34 of electrically conductive wire and/or an electrically conductive wire wound/arranged in a helical manner around the toroidal glass carrier 32. The coil 34 can be formed by a plurality of winding turns 35 which are wound around the glass carrier 32 and be provided with a return wire 36 which is placed in a groove (not shown) of the glass carrier 32. The groove of the glass carrier 32 may be implemented as shown in FIG. 5 or FIG. 6, but other implementations are also possible. The electrical device 30 is provided with electrical terminals 38 for electrical connectivity.

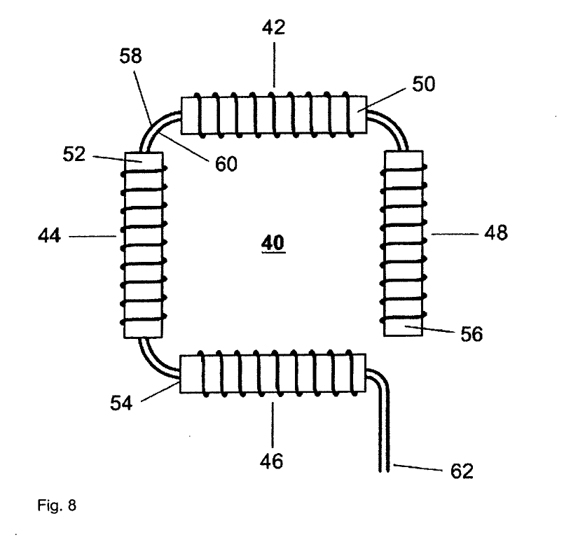

FIG. 8 illustrates an electrical device having an assembly of four coils with straight glass carriers, wherein the coils are uniformly and symmetrically arranged and wherein the assembly is used as a Rogowski coil according to an exemplary embodiment of the disclosure. As shown in FIG. 8, an assembly 40 of at least four identical coils 42, 44, 46, 48 electrically connected in series using conductors 58 where the coils are wound on straight glass carriers 50, 52, 54, 56 and where they are uniformly and symmetrically arranged, e.g. at one side of a square, the assembly of coils 40 being used as a Rogowski coil. The cross section of the carriers 50, 52, 54, 56 may be of any suitable shape, for example circular or oval. The assembly of coils 40 can also provided with a return wire 60 and with electrical terminals 62 for electrical connectivity.

FIG. 7 and FIG. 8 represent each illustrates an electrical device 30, 40 according to the disclosure, for example to be used as a Rogowski coil, wherein the electrical device includes at least one coil 34, 42, 44 of electrically conductive wire wound around a glass carrier and is provided with a return wire 36, 60. The return wire 36, 60 makes the electrical device 30, 40 insensitive to magnetic fields perpendicular to the path of the electrical device 30, 40, however, it may not be specified in any application.

Furthermore, as already mentioned above, the dimensions of the coils depend on the respective carriers which are provided as glass carriers since it has been found that glass carriers have excellent dimensional and physical stability, e.g., such carriers keep their dimensions independent from impacts such as temperature expansion, water absorption, or aging.

Exemplary embodiments of this disclosure are directed to the material and its properties provided for manufacture of carriers for electrical devices, such as coils, for example for Rogowski coils.

The present disclosure also includes any combination of exemplary embodiments as well as individual features and developments provided they do not exclude each other.

Thus, it will be appreciated by those skilled in the art that the present invention can be embodied in other specific forms without departing from the spirit or essential characteristics thereof. The presently disclosed embodiments are therefore considered in all respects to be illustrative and not restricted. The scope of the invention is indicated by the appended claims rather than the foregoing description and all changes that come within the meaning and range and equivalence thereof are intended to be embraced therein.

### REFERENCE LIST

10 first embodiment of a glass carrier
12 oval cross section
14 second embodiment of a glass carrier
16 circular cross section
18 third embodiment of a glass carrier
19 fourth embodiment of a glass carrier
20 fifth embodiment of a glass carrier
22 groove for the return wire
24 oval cross section with hollow resulting from the groove
26 sixth embodiment of a glass carrier
28 groove for the return wire
30 electrical device according to the disclosure (Rogowski Coil)
32 glass carrier
34 toroidal coil
35 winding turns
36 return wire
38 electrical terminals
40 electrical device according to the disclosure comprising an assembly of coils
42, 44, 46, 48 coils
50, 52, 54, 56 straight glass carriers
58 conductor
60 return wire
62 electrical terminals

What is claimed is:

1. An electrical device for measuring alternating current or current pulses, comprising:
at least one coil of electrically conductive wire being wound around a non-magnetic carrier,
wherein the non-magnetic carrier is made of glass.

2. The electrical device according to claim 1, wherein at least one coil of wire being wound around a non-magnetic carrier is a toroid, or an oval, or elliptic ring.

3. The electrical device according to claim 1, comprising:
an assembly of at least two coils, wherein the coils are electrically connected in series,
wherein each coil is wound on a non-magnetic carrier, and
wherein the coils are symmetrically arranged such that they form a closed or almost closed loop.

4. The electrical device according to claim 1, wherein, the non-magnetic carrier is made of glass with a low glass transition temperature.

5. The electrical device according to claim 1, wherein the glass transition temperature of the glass material for the non-magnetic carrier is between 200° C. and 700° C.

6. The electrical device according to claim 1, wherein the non-magnetic carrier is made of silicon dioxide mixed with other ingredients.

7. The electrical device according to claim 6, wherein the non-magnetic carrier is made of soda-lime glass or borosilicate glass.

8. The electrical device according to claim 1 wherein the non-magnetic carrier is manufactured employing a glass molding or glass pressing process.

9. The electrical device according to claim 1, wherein the non-magnetic carrier is manufactured employing a precision glass molding process or is made of precision molding glass.

10. The electrical device according to claim 1, wherein a return wire is lead from one end of the coil or assembly of coils to another end of the coil or assembly of coils, so that both wire terminals are at a same end of the coil or assembly of coils.

11. The electrical device according to claim 1, wherein a groove is provided in the non-magnetic carrier such that the return wire can be located in the groove.

12. The electrical device according to claim 11, wherein the groove passes trough the centre or close to the centre or centre axis of the coil.

13. The electrical device according to claim 1, wherein the non-magnetic carrier is covered with a polymer layer.

14. The electrical device according to claim 1, wherein the electrical coil or assembly of coils is partly or totally enclosed in an electrical shield which includes one or more pieces of conductive or semi-conductive material.

15. The electrical device according to claim 14, wherein the electrical shield includes metal, plastic loaded with conductive fillers, or plastic covered with one or more metallization layers.

16. The electrical device according to claim 2, wherein a return wire is lead from one end of the coil or assembly of coils to another end of the coil or assembly of coils, so that both wire terminals are at a same end of the coil or assembly of coils.

17. The electrical device according to claim 2, wherein a groove is provided in the non-magnetic carrier such that the return wire can be located in the groove.

18. The electrical device according to claim 3, wherein a return wire is lead from one end of the coil or assembly of coils to another end of the coil or assembly of coils, so that both wire terminals are at a same end of the coil or assembly of coils.

19. The electrical device according to claim 3, wherein a groove is provided in the non-magnetic carrier such that the return wire can be located in the groove.

20. A current sensor comprising:
an electrical device according to claim 1 configured to be used in electrical power transmission and distribution or in electrical energy metering.
